(19) United States
(12) Patent Application Publication
(10) Pub. No.: US 2015/0006991 A1
(43) Pub. Date: Jan. 1, 2015

(54) GRACEFUL DEGRADATION-FORWARD ERROR CORRECTION METHOD AND APPARATUS FOR PERFORMING SAME

(71) Applicant: Electronics and Telecommunications Research Institute, Daejeon (KR)

(72) Inventors: Seok Ho Won, Daejeon (KR); Sun Hyoung Kwon, Seoul (KR); Ho Kyom Kim, Daejeon (KR); Jong Soo Lim, Daejeon (KR); O Hyung Kwon, Daejeon (KR)

(21) Appl. No.: 14/374,690

(22) PCT Filed: Jan. 24, 2013
(86) PCT No.: PCT/KR2013/000572

§ 371 Date: Jul. 25, 2014

(30) Foreign Application Priority Data
Jan. 25, 2012 (KR) 10-2012-0007404
Nov. 7, 2012 (KR) 10-2012-0125373
Jan. 15, 2013 (KR) 10-2013-0004438

(51) Int. Cl. H03M 13/13; G06F 11/10; H03M 13/29

(52) U.S. Cl. CPC H03M 13/13; H03M 13/2906; G06F 11/10
USPC 714/755; 714/776

(57) ABSTRACT

Disclosed are a graceful degradation-forward error correction method and an apparatus for performing same. A graceful degradation-forward error correction method determines an encoding unit data group constituted by a predetermined number of time intervals for a data stream input in a time-sequential manner, determines a reference data group to be used in generating a parity frame in each time interval of the encoding unit data group, generates a parity frame using the determined at least one reference data group, and assigns the generated parity frame to at least one time interval from among a plurality of time intervals including time intervals constituting the encoding unit data group based on a predetermined rule. Thus, a lost packet can be recovered even when the packet of a continuous long interval is lost, and consequentially, a seamless service may be provided.

### TECHNICAL FIELD

Example embodiments of the present invention relate in general to error correction technology, and more specifically, to a graceful degradation-forward error correction (GD-FEC) method capable of being applied to multimedia broadcast and multicast service, and an apparatus thereof.

### BACKGROUND ART

In multimedia packet communication through a mobile communication network, packet loss may occur due to the characteristics of mobile communication environments. For example, when a terminal passes through a shadow region, such as the back of a building, a tunnel, etc., burst packet loss may occur since the terminal cannot receive data.

As a protection method against such packet loss, a packet redirection method using Automatic Repeat Request (ARQ) or Hybrid ARQ (HARQ) has been proposed, however, the method fails to solve a problem of service quality degradation due to delay caused by packet redirection. That is, in non-realtime service, such as replaying stored video, delay causes little problem, but in real-time service, such as interactive video or video conferencing, delay has significantly great influence on service quality.

As a method for recovering lost packets without redirection in consideration of these conditions, application layer-forward error correction (AL-FEC) has been used.

AL-FEC increases redundancy in order to increase a coding rate according to an increase of packet loss. Also, in order to increase redundancy, the AL-FEC uses a method in which a receiver decides a code rate adaptively to a channel using a rateless code such as Fountain code, or a method of feeding the state of a channel back to a transmitter terminal from a lower layer by using the concept of an reception application layer or a cross layer to adjust AL-FEC redundancy of the transmitter terminal.

However, there may occur packet loss over a long period that cannot be recovered by the AL-FEC, and accordingly, a packet recovery method capable of providing seamless service while minimizing delay is needed.

### DISCLOSURE

### Technical Problem

Accordingly, example embodiments of the present invention are provided to substantially obviate one or more problems due to limitations and disadvantages of the related art.

An example embodiment of the present invention provides a graceful degradation-forward error correction (GD-FEC) method capable of recovering continuous data loss while minimizing delay.

Another example embodiment of the present invention also provides a GD-FEC apparatus for performing the GD-FEC method.

### Technical Solution

In some example embodiments, a graceful degradation-forward error correction (GD-FEC) method includes: deciding a data group for encoding in a plurality of data streams being successively received over time, the data group for encoding configured with a predetermined number of time durations; deciding at least one reference data group to be used for generating a parity frame in the individual time durations of the data group for encoding; generating a parity frame using the at least one reference data group; and distributing the parity frame into at least one time duration of a plurality of time durations including the time durations configuring the data group for encoding, according to a predetermined rule.

The deciding of the reference data group may include: comparing the time lengths of frames corresponding to a reference data type having a highest priority among data types included in the individual data durations of the data group for encoding, to each other; deciding the size of a frame having a longest time length among the frames, as a size of the reference data group; and deciding the reference data group including at least one data type according to predetermined recovery priority in each time duration, based on the size of the reference data group.

The generating of the parity frame may include: concatenating the reference data group to configure source data; and performing encoding on the source data to generate the parity frame.

The performing of the encoding on the source data to generate the parity frame may include performing RaptorQ-like encoding on the source data to generate the parity frame.

The generating of the parity frame may include generating the parity frame according to a predetermined period configured in unit of the reference data group.

The distributing of the parity frame may include distributing the parity frame to a time duration before the time durations configuring the data group for encoding, or to at least one time duration among the time durations configuring the data group for encoding, according to a predetermined rule.

The distributing of the parity frame may include dividing the parity frame to generate two or more divided parity frames each having a predetermined length; and distributing the two or more divided parity frames to time durations before the time durations configuring the data group for encoding, or to two or more time durations among the time durations configuring the data group for encoding. The generating of the divided parity frames may include deciding the size of each divided parity frame, based on the number of reference data groups having to be recovered among a plurality of reference data groups each corresponding to the reference data group and the size of each reference data group.

The deciding of the data group for encoding may include: deciding a Group of Picture (GoP) for each time duration having a predetermined length in pictures successively received over time; and deciding the data group for encoding configured with a predetermined number of GoPs each corresponding to the GoP.

The deciding of the reference data group may include: comparing the lengths of I pictures among picture types included in the individual GoPs configuring the data group for encoding, to each other; deciding the length of an I picture having a longest length among the I pictures included in the individual GoPs, as a (the) size of the reference data group; and deciding the reference data group including at least one picture type according to predetermined recovery priority in each GoP, based on the size of the reference data group.

In other example embodiments, a graceful degradation-forward error correction (GD-FEC) method which is performed by a transmission apparatus for transmitting multimedia data includes: deciding a data group for encoding configured with a predetermined number of time durations in a received data stream; deciding at least one reference data group to be used for generating a parity frame in the individual time durations included in the data group for encoding; generating a parity frame using the at least one reference data group; and transmitting the parity frame before transmitting data included in the data group for encoding.

The generating of the parity frame may include: concatenating the reference data group to configure source data; and performing RaptorQ-like encoding on the source data to generate the parity frame.

The transmitting of the parity frame before transmitting the data included in the data group for encoding may include transmitting the parity frame for a time duration in which the received data stream is buffered.

The deciding of the data group for encoding configured with the predetermined number of time durations in the received data stream may include deciding the time durations of the data group for encoding as the same duration per which a specific protocol segments and processes a file.

The deciding of the data group for encoding configured with the predetermined number of time durations in the received data stream may include deciding the time durations of the data group for encoding as the same duration as a file segment duration of a file delivery over unidirectional transport (FLUTE) protocol.

The GD-FEC method may further include performing interleaving in unit of a segment packet resulting from dividing a segment file included in the file segment duration of the FLUTE protocol.

In other example embodiments, a graceful degradation-forward error correction (GD-FEC) apparatus includes: a first encoding layer configured to perform GD-FEC on received multimedia data; a transport protocol processing layer configured to perform transport protocol processing on the data subject to the GD-FEC; and a second encoding layer configured to perform application layer-forward error correction (AL-FEC) on the data subject to the transport protocol processing.

The first encoding layer may perform the GD-FEC according to the type of the received multimedia data.

### Advantageous Effects

As described above, according to the method and apparatus for GD-FEC, packet loss over a long period which cannot be recovered by application layer-forward error correction (AL-FEC), may be recovered, thereby providing seamless service.

Also, by minimizing the size of redundancy data to be added for recovering lost data, encoding gain may be improved, resulting in improvement of transmission efficiency.

In addition, by minimizing delay due to GD-FEC encoding and decoding, loss compensation efficiency may be improved, which contributes to quality of service (QoS).

### DESCRIPTION OF DRAWINGS

FIG. 1 is a conceptual view showing a first type GD-FEC method according to an embodiment of the present invention;

FIG. 2 is a conceptual view showing a second type GD-FEC method according to an embodiment of the present invention;

FIG. 3 is a conceptual view showing a third type GD-FEC method according to an embodiment of the present invention;

FIG. 4 is a timing diagram showing frame configuration by the third type GD-FEC method shown in FIG. 3 in detail;

FIG. 5 is a conceptual view showing a fourth type GD-FEC method according to an embodiment of the present invention;

FIG. 6 is a timing diagram showing frame configuration by the fourth type GD-FEC method shown in FIG. 5 in detail;

FIG. 7 shows the header format of a parity frame that is used in a GD-FEC method according to an embodiment of the present invention;

FIG. 8 is a conceptual view for explaining a processing procedure of the GD-FEC method;

FIG. 9 shows locations at which the GD-FEC method is included in a 3GPP transmission protocol;

FIG. 10 is a view for explaining a processing procedure of application layer-forward error correction (AL-FEC) that is processed after the GD-FEC method is performed;

FIG. 11 is a view for explaining a process for minimizing decoding delay in the GD-FEC method; and

FIG. 12 is a view for explain a process for minimizing decoding delay in a GD-FEC method according to another embodiment of the present invention.

Throughout the drawings and the detailed description, unless otherwise described, the same drawing reference numerals will be understood to refer to the same elements, features, and structures. The relative size and depiction of these elements may be exaggerated for clarity, illustration, and convenience.

### MODES OF THE INVENTION

The following description is provided to assist the reader in gaining a comprehensive understanding of the methods, apparatuses, and/or systems described herein. Accordingly, various changes, modifications, and equivalents of the methods, apparatuses, and/or systems described herein will be suggested to those of ordinary skill in the art. Also, descriptions of well-known functions and constructions may be omitted for increased clarity and conciseness.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present invention will be described in detail with reference to the appended drawings. In the following description, for easy understanding, like numbers refer to like elements throughout the description of the figures, and the same elements will not be described further.

A graceful degradation-forward error correction (GD-FEC) method according to an embodiment of the present invention provides an optimized parity frame generation method for protecting burst packet loss, and the GD-FEC method is combined with a payload formatting method in order to disperse influence of inevitable delay to prevent the delay from influencing service, thereby improving coding gain and packet loss compensation efficiency.

For easy description on the configuration and operation of the present invention, formats, timing diagrams, encoding methods, parity bit generation methods, frame configuration and distribution methods, parity frame arrangement methods in consideration of transmission delay and reception delay, etc. of various types of GD-FEC methods according to some embodiments of the present invention will be first described.

The following description for the various types of GD-FEC methods will be given based on video data, however, the GD-FEC methods may be applied to multimedia data, such as audio, dynamic and interactive multimedia scenes (DIMS), text, etc., as well as video data.

First Type GD-FEC

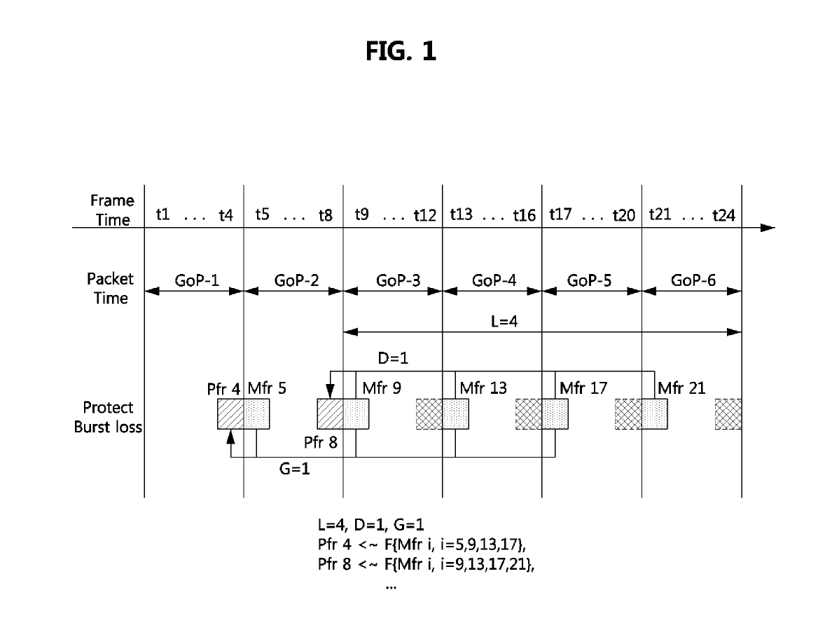

FIG. 1 is a conceptual view showing a first type GD-FEC method according to an embodiment of the present invention, and shows a timing diagram, an encoding method, and parity frame configuration, distribution, and arrangement methods of the first type GD-FEC method.

Referring to FIG. 1, if a group of GoPs (Group of picture) participating in one GD-FEC encoding process is G, and the number of elements belonging to G is L, the lengths of I frames having to be recovered upon occurrence of burst packet loss for L GoPs are compared to each other to select the longest I frame, and the size of the selected I frame is decided as the size of a macro frame (Mfr). Here, GoP means a group configured with a plurality of pictures (or frames), and in the present embodiments, it is assumed that a GoP is configured with four frame time durations. The frame is a frame encoded using only information in a picture, regardless of the previous and next pictures (or frames). Also, the macro frame Mfr refers to a predetermined size of a frame group configuring bits included (or “included bits”) to generate a parity frame of GD-FEC.

Meanwhile, in each GoP which is an element configuring G, an I frame is preferentially selected, and then frames to be preferentially protected according to predetermined priorities, are sequentially selected to configure a macro frame Mfr corresponding to the GoP according to the length of a macro frame Mfr. Here, the predetermined priorities may be recovery priorities upon occurrence of burst packet loss, and for example, the predetermined priorities may be set to the order of I, P, and B frames. The P frame is a picture obtained by interpicture forward predictive coding, and the B picture (frame?) is a picture obtained by interpicture bi-directional predictive coding.

Then, by concatenating the macro frames Mfr to configure a source symbol, and performing GD-FEC encoding on the source symbol, a parity frame Pfr is obtained as the result of the GD-FEC encoding.

The process of generating the parity frame in the first type GD-FEC may be expressed as equation 1, below.

$$\begin{matrix}\begin{matrix}Pfr 4 < \sim F \{ Mfr i , i = 5 , 9 , 13 , 17 ) , \\ Pfr 8 < \sim F \{ Mfr i , i = 9 , 13 , 17 , 21 ) ,\end{matrix} \\ ⋯\end{matrix} \qquad ( 1 )$$

In equation 1, an operator “<˜” is a function of generating a parity frame Pfr, wherein the function inserts the result obtained by performing RaptorQ-like encoding on a source symbol configured by concatenating macro frames Mfr in G, into each GoP in G. Also, “F” represents the RaptorQ-like encoding function, and “i” represents a frame time. The length of the parity frame Pfr is decided by theorem 1 and corollary 1, which will be described later.

Parameters of the first type GD-FEC are L=4, D=1, and G=1. Here, D is the number of GoPs in which the parity frame Pfr acquired as the result of GD-FEC encoding is carried, and in the first type GD-FEC shown in FIG. 1, D=1 since a GoP carries a parity frame Pfr. Also, G is a time duration per which a parity frame Pfr is generated by concatenating corresponding macro frames Mfr of G and applying the function F. If G=1 as shown in FIG. 1, a parity frame Pfr is generated every GoP. However, the values of the parameters L, D, and G are only exemplary. That is, the values of the parameters L, D, and G may be appropriately set depending on transmission delay or reception delay requirements. Also, the current embodiment shows an example in which a parity frame Pfr is located in the final frame time of each GoP period, however, this is only exemplary. Also, there are various methods of selecting macro frames Mfr to be used for generating each parity frame Pfr.

Hereinafter, the configuration of the first type GD-FEC will be described in more detail with reference to equation 1. By concatenating four macro frames Mfr5, Mfr9, Mfr13, and Mfr17 respectively included in four GoPs GoP-2, GoP-3, GoP-4, and GoP-5 to configure a source symbol, and performing RaptorQ-like encoding (that is, the function F) on the source symbol, a parity frame Pfr4 is generated and located in a frame time duration t4.

Meanwhile, since the first type GD-FEC relates to an example in which G=1 and a GoP is configured with four frame time durations, the second parity frame Pfr8 will be located in a frame time duration t8. As expressed in equation 1, the parity frame Pfr8 is generated by concatenating four macro frames Mfr9, Mfr13, Mfr17, and Mfr21 respectively included in four GoPs GoP-3, GoP-4, GoP-5, and GoP-6 to configure a source symbol, and performing RaptorQ-like encoding on the source symbol.

Second Type GD-FEC

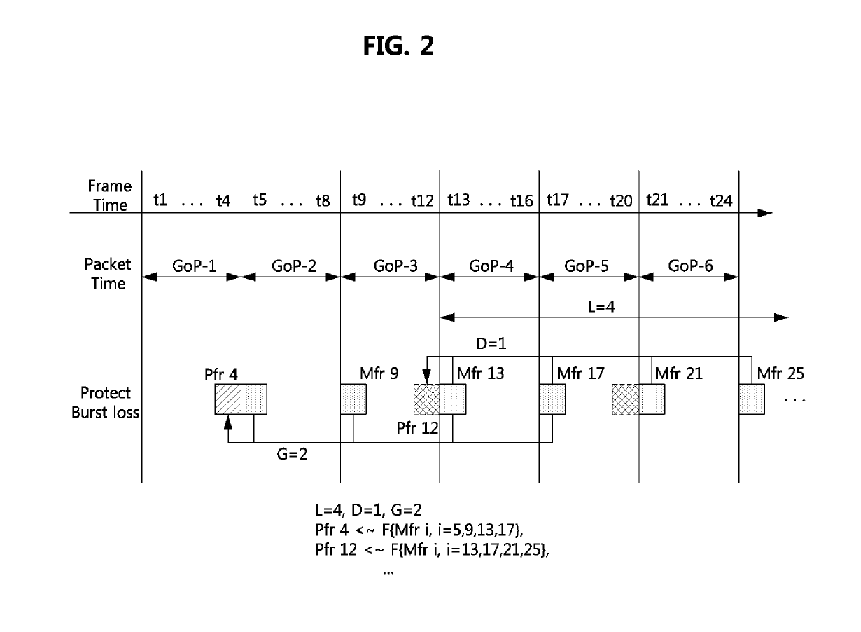

FIG. 2 is a conceptual view showing a second type GD-FEC method according to an embodiment of the present invention, and shows a timing diagram, an encoding method, and parity frame configuration, distribution, and arrangement methods for the second type GD-FEC method.

Hereinafter, the configuration and method of the second type GD-FEC will be described with reference to FIG. 2.

As shown in FIG. 2, parameters of the second type GD-FEC may be set to L=4, D=1, and G=2, and a GoP may be configured with four frame time durations. The meanings of the parameters L, D, and G and a method of generating a macro frame Mfr have the same as those described above with reference to FIG. 1.

In the second type GD-FEC, since L=4, G includes four GoPs, and a parity frame Pfr is generated by concatenating macro frames Mfr respectively included in the four GoPs to configure a source symbol, and performing RaptorQ-like encoding on the source symbol.

Meanwhile, in the second type GD-FEC, since G=2, a parity frame Pfr is generated every two GoPs, and since D=1, a parity frame Pfr is carried in a GoP.

The process of generating the parity frame Pfr in the second type GD-FEC may be expressed as equation 2, below.

$$\begin{matrix}\begin{matrix}Pfr 4 < \sim F \{ Mfr i , i = 5 , 9 , 13 , 17 ) , \\ Pfr 12 < \sim F \{ Mfr i , i = 13 , 17 , 21 , 25 ) ,\end{matrix} \\ ⋯\end{matrix} \qquad ( 2 )$$

In equation 2, the meanings of an (the) operator “<˜”, “F”, and “i” have been described above in connection with equation 1.

As expressed in equation 2, a method of generating the first parity frame Pfr4 of the second type GD-FEC, and a location to which the parity frame Pfr4 is applied, are the same as in the first type GD-FEC, however, in the second type GD-FEC, since G=2, a method of generating the second parity frame Pfr12 and a location to which the parity frame Pfr12 is applied, are different from in the first type GD-FEC.

That is, in the second type GD-FEC, since G=2, the location to which the second parity frame Pfr12 is applied, may be a frame time duration t12 of GoP-3, and the parity frame Pfr12 may be generated based on four macro frames Mfr13, Mfr 17, Mfr 21, and Mfr 25 respectively included in four GoPs (that is, GoP-4, GoP-5, GoP-6, and GoP-7) successively located starting from GoP-4.

In the configuration of the second type GD-FEC shown in FIG. 2, the values of the parameters L, D, and G are only exemplary, and accordingly, the values of the parameters L, D, and G may be appropriately set depending on transmission delay or reception delay requirements. Also, the current embodiment shows an example in which a parity frame Pfr is located in the final frame time of each GoP period, however, this is also only exemplary. Also, there are various methods of selecting macro frames Mfr to be used for generating each parity frame Pfr.

Third Type GD-FEC

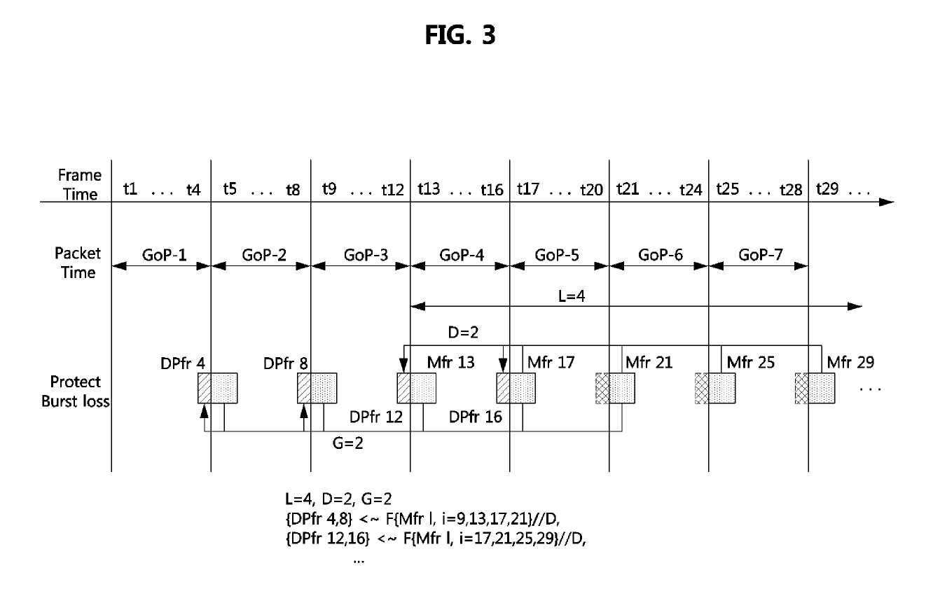

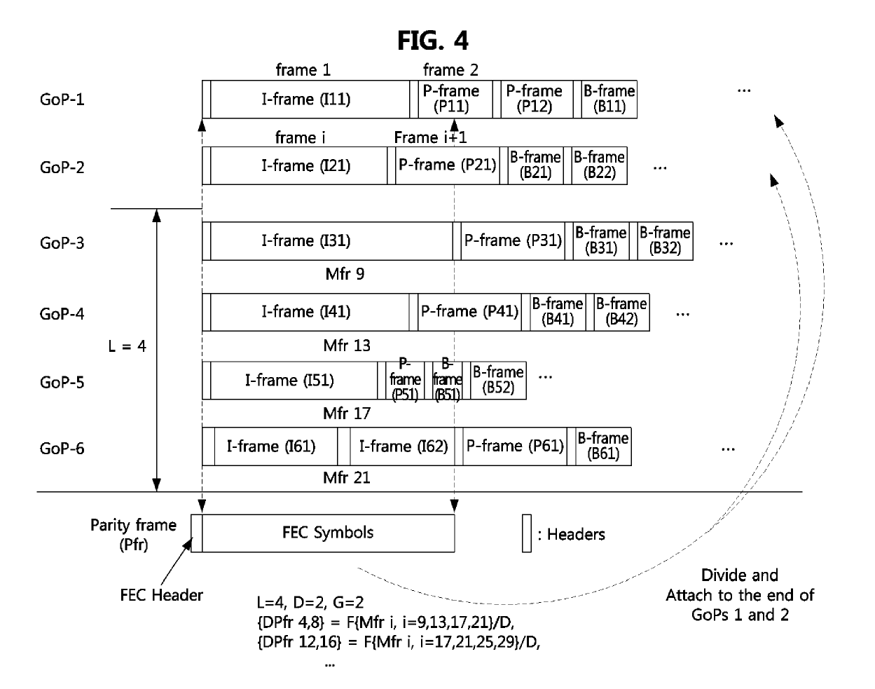

FIG. 3 is a conceptual view showing a third type GD-FEC method according to an embodiment of the present invention, and shows a timing diagram, an encoding method, and parity frame configuration, distribution, and arrangement methods for the third type GD-FEC method. FIG. 4 is a timing diagram showing frame configuration by the third type GD-FEC method shown in FIG. 3 in detail;

Hereinafter, the third type GD-FEC method will be described in more detail with reference to FIGS. 3 and 4.

In FIG. 3, L represents groups that input source information to be subject to GD-FEC encoding. If a group of GoPs participating in one GD-FEC encoding process is G, and the number of elements belonging to G is L, the lengths of I frames having to be recovered upon occurrence of burst packet loss for L GoPs are compared to each other to select the longest I frame, and the size of the selected I frame is decided as the size of a macro frame (Mfr).

For example, if the individual GoPs shown in FIG. 3 are configured as shown in FIG. 4, the longest one among the I frames of GoPs GoP-3, GoP-4, GoP-5, and GoP-6 included in a GoP group G, is a frame I31, and accordingly, the length of the frame I31 is decided as the size of a macro frame Mfr.

Also, in each GoP which is an element configuring G, an I frame is preferentially selected, and then frames to be preferentially protected according to predetermined priorities, are sequentially selected to configure a macro frame Mfr corresponding to the GoP according to the length of a macro frame Mfr. Here, the predetermined priorities may be recovery priorities upon occurrence of burst packet loss, and for example, the predetermined priorities may be set to the order of I, P, and B frames.

For example, as shown in FIG. 4, if the size of a macro frame Mfr9 is decided based on the length of the longest frame I31 of I frames respectively included in the GoPs GoP-3, GoP-4, GoP-5 and GoP-6, macro frames Mfr13, Mfr17, and Mfr21 are configured to have the same size as the macro frame Mfr 9 in the GoPs GoP-4, GoP-5, and GoP-6.

That is, as shown in FIG. 4, in the GoP-4, the macro frame Mfr 13 may be configured with an I frame I41 and a part of a P frame P41 according to predetermined priorities, and in the GoP-5, the macro frame Mfr 17 may be configured with an I frame I51, a P frame P51, and a part of a B frame B51 according to predetermined priorities. Also, in the GoP-6, the macro frame Mfr 21 may be configured with two I frames I61 and I62.

After macro frames Mfr are decided in the individual GoPs included in G, as described above, by concatenating the macro frames Mfr to configure a source symbol and performing GD-FEC encoding on the source symbol, divided parity frames DPfr are acquired as the result of the GD-FEC encoding. Each divided parity frame DPfr is a predetermined size of a frame divided from a parity frame Pfr, the parity frame Pfr generated by concatenating macro frames Mfr of a GoP group consisting of L GoPs and performing GD-FEC encoding, in order to add the parity frame Pfr to an appropriate location (for example, the final frame time duration) of each GoP.

Successively, the divided parity frames DPfr are added to corresponding GoPs.

In the third type GD-FEC, the process of generating and adding the divided parity frames DPfr may be expressed as equation 3, below.

$$\begin{matrix}\begin{matrix}\{ DPfr 4 , 8 \} < \sim F \{ Mfr i , i = 9 , 13 , 17 , 21 \} // D , \\ \{ DPfr 12 , 16 \} < \sim F \{ Mfr i , i = 17 , 21 , 25 , 29 \} // D ,\end{matrix} \\ ⋯\end{matrix} \qquad ( 3 )$$

In equation 3, an (the) operator “<˜” is a function of generating a parity frame Pfr, wherein the function inserts the result obtained by performing RaptorQ-like encoding on a source symbol configured by concatenating macro frames Mfr in G, into each GoP in G. Also, an (the) operator “//” is a function of dividing the length of a parity frame resulting from RaptorQ-like encoding by D to generate divided parity frames DPfr. Also, “F” represents the RaptorQ-like encoding function, and “i” represents a frame time. The length of a divided parity frame DPfr is decided by corollary 2, which will be described later.

Parameters of the third type GD-FEC may be given as L=4, D=2, and G=2. Here, the meanings of the parameters D and G are the same as those described above with reference to FIG. 1.

Meanwhile, in the third type GD-FEC, since G=2, a parity frame Pfr is generated every two GoPs, and since D=2, a parity frame Pfr is divided to two divided parity frames DPfr, and each divided parity frame DPfr is located in a GoP. As a result, a parity frame Pfr is located in two GoPs.

In the third type GD-FEC shown in FIGS. 3 and 4, the values of the parameters L, D, and G are only exemplary. That is, the values of the parameters L, D, and G may be appropriately set depending on transmission delay or reception delay requirements. Also, the current embodiment shows an example in which a divided parity frame DPfr is located in the final frame time duration of each GoP period, however, this is only exemplary. Also, there are various methods of selecting macro frames Mfr to be used for generating each parity frame Pfr.

Fourth Type GD-FEC

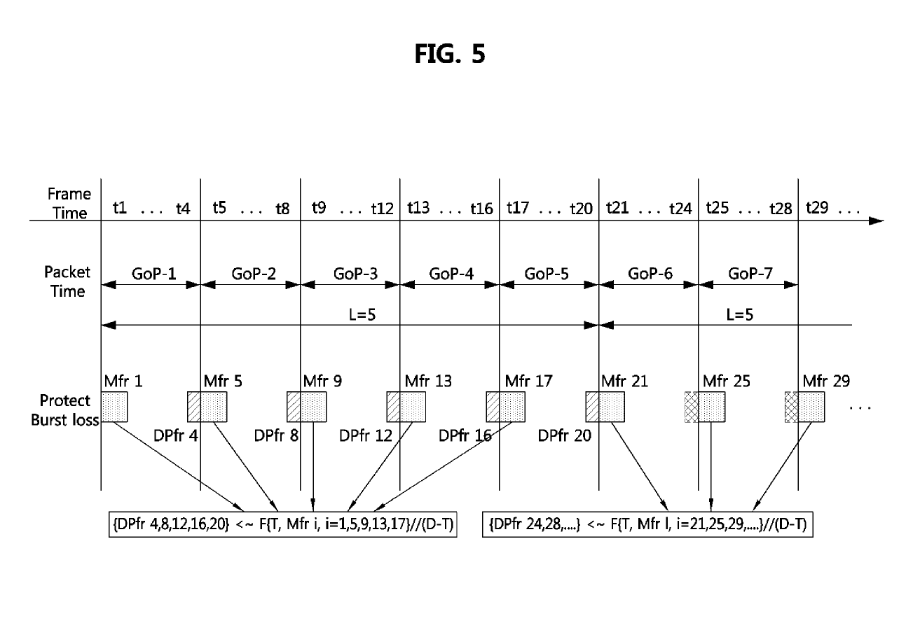

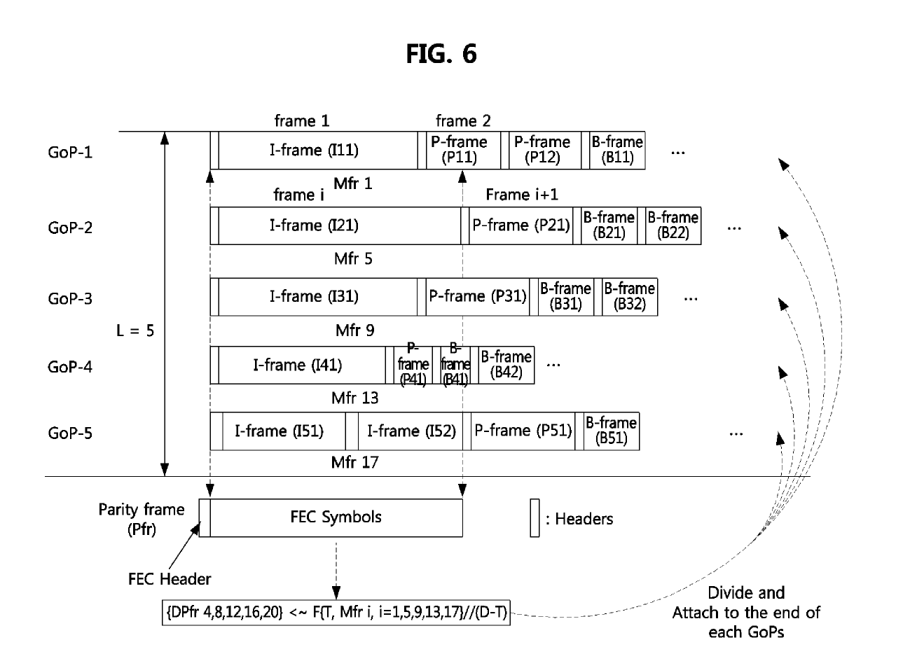

FIG. 5 is a conceptual view showing a fourth type GD-FEC method according to an embodiment of the present invention, and shows a timing diagram, an encoding method, and parity frame configuration, distribution, and arrangement methods for the fourth type GD-FEC code (method?). Also, FIG. 6 is a timing diagram showing frame configuration by the fourth type GD-FEC method shown in FIG. 5 in detail.

Hereinafter, the fourth type GD-FEC method will be described in more detail with reference to FIGS. 5 and 6.

In FIG. 5, L represents groups that input source information to be subject to GD-FEC encoding. If a group of GoPs participating in one GD-FEC encoding process is G, and the number of elements belonging to G is L, the lengths of I frames having to be recovered upon occurrence of burst packet loss for L GoPs are compared to each other to select the longest I frame, and the size of the selected I frame is decided as the size of a macro frame Mfr. The fourth type GD-FEC shows an example in which the parameter L is set to 5. However, the value of the parameter L may be appropriately set depending on transmission delay or reception delay requirements.

If the individual GoPs shown in FIG. 5 are configured as shown in FIG. 6, the longest one among the I frames of GoP-1, GoP-2, GoP-3, GoP-4, and GoP-5 included in a GoP group G, is a frame I21, and accordingly, the length of the frame I21 is decided as the size of a macro frame Mfr.

Also, in each GoP which is an element configuring G, an I frame is preferentially selected, and then frames to be preferentially protected according to predetermined priorities, are sequentially selected to configure a macro frame Mfr corresponding to the GoP according to the length of a macro frame Mfr. Here, the predetermined priorities may be recovery priorities upon occurrence of burst packet loss, and for example, the predetermined priorities may be set to the order of I, P, and B frames.

For example, as shown in FIG. 6, if the size of a macro frame Mfr 5 is decided based on the length of the longest frame I21 of I frames respectively included in the GoPs GoP1, GoP-2, GoP-3, GoP-4 and GoP-5, macro frames Mfr 1, Mfr 9, Mfr13, and Mfr 17 are configured to have the same size as the macro frame Mfr 5 in the GoPs GoP-1, GoP-3, GoP-4, and GoP-5.

That is, as shown in FIG. 6, in the GoP-1, a macro frame Mfr 1 may be configured with an I frame I11 and a part of a P frame P11 according to predetermined priorities, and in the GoP-3, a macro frame Mfr 9 may be configured with an I frame I31 and a part of a P frame P31 according to predetermined priorities. Also, in the GoP-4, a macro frame Mfr 13 may be configured with an I frame I41, a P frame P41, and a part of a B frame B41, and in the GoP-5, a macro frame Mfr 17 may be configured with two I frames I51 and I52.

After macro frames Mfr are decided in the individual GoPs included in G, as described above, by concatenating the macro frames Mfr to configure a source symbol and performing GD-FEC encoding on the source symbol, divided parity frames DPfr are acquired as the result of the GD-FEC encoding. The divided parity frames DPfr are added to corresponding GoPs.

The process of generating and adding the divided parity frames DPfr in the fourth type GD-FEC may be expressed as equation 4, below.

$$\begin{matrix}\begin{matrix}\{ DPfr 4 , 8 , 12 , 16 , 20 \} < \sim F \{ T , Mfr i , i = 1 , 5 , 9 , 13 , 17 \} // ( D - T ) , \\ \begin{matrix}\{ DPfr 24 , 28 , 32 , 36 , 40 \} < \sim \\ F \{ T , Mfr i , i = 21 , 25 , 29 , 33 , 37 \} // ( D - T )\end{matrix} ,\end{matrix} \\ ⋯\end{matrix} \qquad ( 4 )$$

In equation 4, an (the) operator “<˜” is a function of generating divided parity frames DPfr, wherein the function inserts the result obtained by performing RaptorQ-like encoding on a source symbol configured by concatenating macro frames Mfr in G, into each GoP in G. Also, an (the) operator “//” is a function of dividing the length of a parity frame resulting from RaptorQ-like encoding by D-T to generate the divided parity frames DPfr. Also, “F” represents the RaptorQ-like encoding function, “T” represents the number of recoverable GoPs, that is, the number of recoverable macro frames Mfr when concatenation loss has occurred between the macro frames Mfr, and “i” represents a frame time. The length of a divided parity frame DPfr is decided by corollary 2, which will be described later.

Hereinafter, theorems are defined in order to deduce corollaries, and corollaries 1 and 2 are defined.

Theorem 1

If it is assumed that a channel capacity C is a bit B for each used channel, a bit rate R satisfies the relationship of R=Bk/(k+m)≦C=B, wherein k represents the length of a message, and m represents the length of a parity.

Also, if it is assumed that loss has generated in α of the message upon bearer transmission, the length of the remaining portion of the message, in which no loss has occurred, becomes (1-α)k, wherein m>αk.

Proof of Theorem 1

In theorem 1, a lost message may be interpreted to be lost when it passes through a binary erasure channel (BEC). Accordingly, an inequality expressed as equation 5 is obtained, and as a result, an inequality expressed as equation 6 has to be satisfied.

$$\begin{matrix}R = B \frac{k}{( 1 - α ) k + m} < C = B ( 1 - \frac{α}{k + m} ) = B \frac{( 1 - α ) k + m}{k + m} < B & ( 5 ) \\ {R}^{′} = \frac{k}{( 1 - α ) k + m} < {C}^{′} = 1 - \frac{α k}{k + m} = \frac{( 1 - α ) k + m}{k + m} < 1 & ( 6 )\end{matrix}$$

If it is assumed that m=αk, R′=1 which is greater than C′, which invalidates the assumption. Accordingly, the inequality of equation 6 is satisfied only when m>αk.

Corollary 1

It is seen from theorem 1 that when loss has generated in a of a message having the length of k bits upon bearer transmission, the required length of parity requires more bits than the lost bits. In this case, if loss recovery is performed using codes (for example, RaptorQ codes) being considered as complete recovery codes, it is possible to configure the length of parity to be close to the length of lost bits. Accordingly, m=αk+ε with respect to a sufficiently small positive number ε, is satisfied.

Corollary 2

The length of a divided parity frame may be calculated by equation 7, below.

$$length ( DPfr ) = [ T \cdot length ( Mfr ) + ɛ ] \frac{1}{D - T} \qquad ( 7 )$$

According to theorem 1 and corollary 1, the amount of parity bits should be set to be larger than the amount of data bits having to be recovered. This means that in order to recover the bits of at least I frames when all frames have been lost due to loss of successive GoPs, more parity bits than the amount of bits of I frames have to be generated.

Consequently, since the length of parity required for recovering lost ak bits is m=αk+ε, the length of parity required for recovering lost T macro frames is [T·length(Mfr)+ε]. If all of T GoPs in G have been lost, desired information can be recovered by preforming RaptorQ-like decoding using D-T GoPs, and accordingly, the length of a divided parity frame required to recover the loss is given as in equation 7.

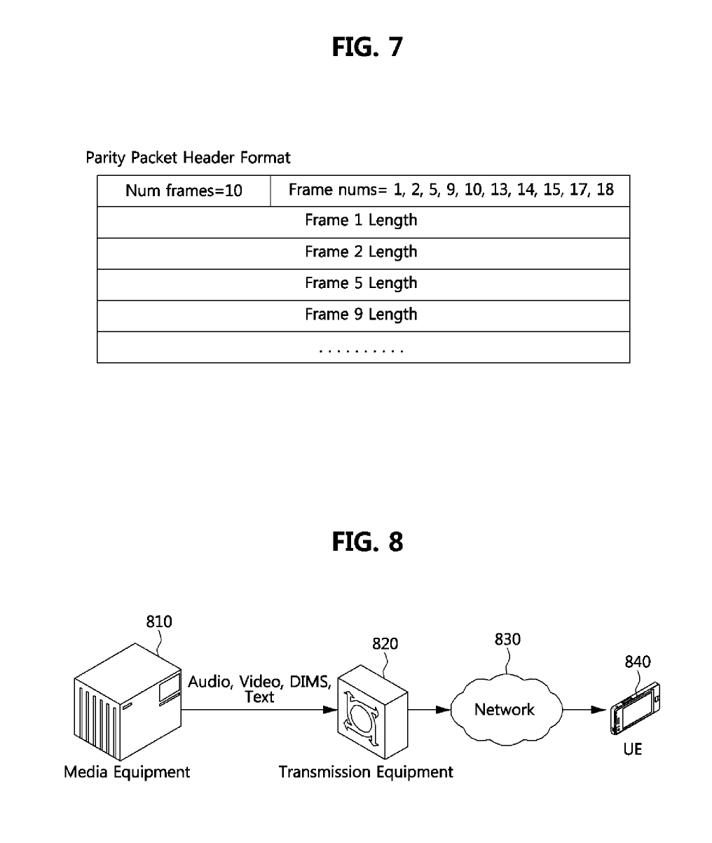

FIG. 7 shows the header format of a parity frame that is used in a GD-FEC method according to an embodiment of the present invention, wherein the header format of the parity frame has been generated by GD-FEC encoding.

Referring to FIG. 7, the header of the parity frame may include a number-of-frames field (Num frames), a frame number field (Frame nums), and frame length fields (Frame n Length, wherein n is a natural number).

The header of the parity frame may omit redundancy fields, and allow compression. Also, other parameter information excluded from the header of the parity frame may be transmitted through out-of-band signaling.

Hereinafter, the processing procedure of the GD-FEC method will be conceptually described, and then sequentially described in detail with reference to a 3^{rd} Generation Partnership Project (3GPP) transmission protocol.

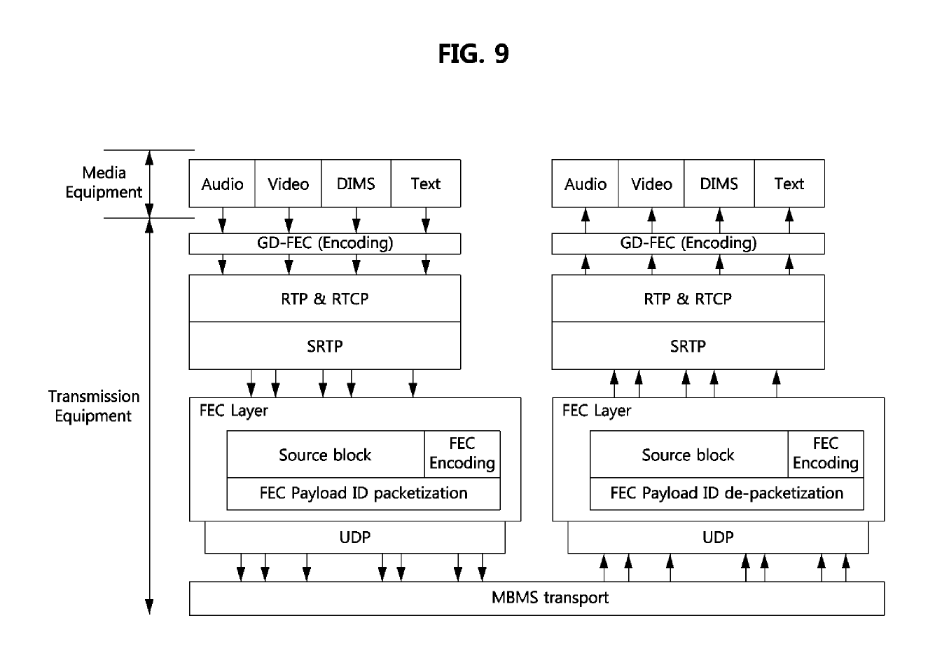

FIG. 8 is a conceptual view for explaining the processing procedure of the GD-FEC method.

Referring to FIG. 8, generally, multimedia data, such as audio, video, dynamic and interactive multimedia scenes (DIMS), text, etc., is transmitted from media equipment 810 to transmission equipment, and then, provided to user equipment (UE) 840 from the transmission equipment 820 through a network 830.

The media equipment 810 may be a content server, and the transmission equipment 820 may be a broadcast multicast service center (BM-SC). Also, the network 830 may be a mobile communication network supporting multimedia broadcast and multicast service (MBMS).

Even though the GD-FEC and application layer-forward error correction (AL-FEC) can improve reliability and robustness of multimedia data transmission, parity data for the GD-FEC and AL-FEC is redundancy data in view of the media equipment 810. Accordingly, neither the GD-FEC nor the AL-FEC should be performed in general-purpose media equipment 810 for provision of multimedia, and the transmission equipment 820 performs the GD-FEC and AL-FEC on multimedia data, such as audio, video, DIMS, text, etc., provided from the media equipment 810.

However, since the GD-FEC needs to distinguish I frames upon encoding and decoding, unlike the AL-FEC, the GD-FEC has to be performed before distinguishing the type or priority of data received by the transmission equipment 820 becomes impossible due to interleaving, encoding, etc.

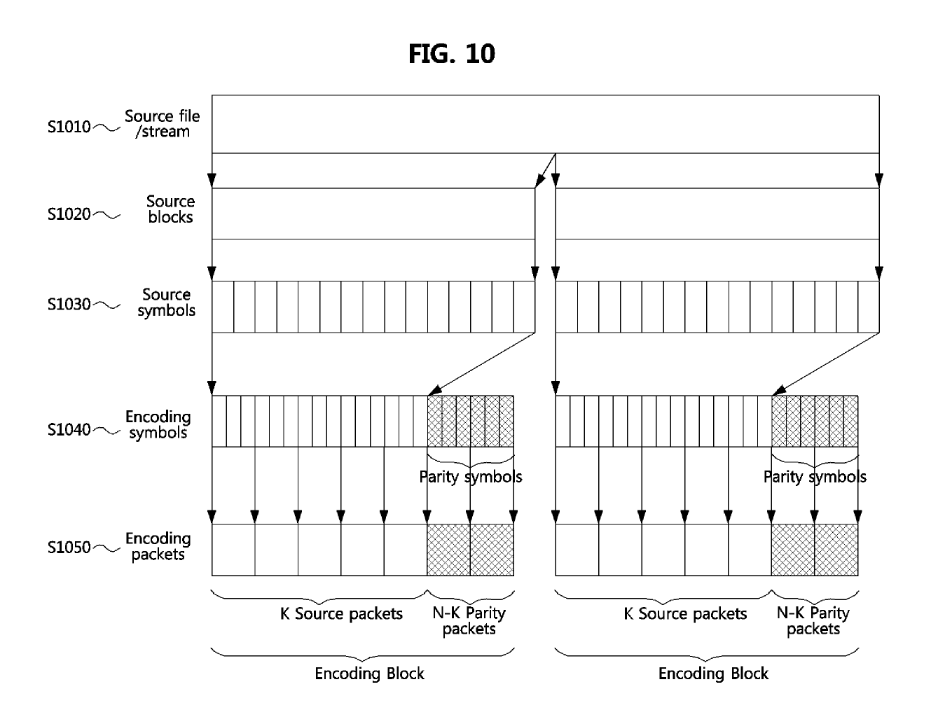

FIG. 9 shows locations at which the GD-FEC method is included in the 3GPP transmission protocol, and shows an example of a protocol performing MBMS transport. Also, FIG. 10 is a view for explaining a processing procedure of AL-FEC that is processed after the GD-FEC method is performed. The GD-FEC method and the AL-FEC method shown in FIGS. 9 and 10, respectively, may be performed by transmission equipment.

As shown in FIG. 9, GD-FEC encoding may be performed in a layer that initially processes received multimedia data, among protocol layers.

That is, GD-FEC encoding may be performed in the uppermost layer among protocol layers, or the upper layer at least, than a layer performing transmission, as shown in FIG. 9.

Meanwhile, the AL-FEC is performed in a layer just below a realtime transport protocol (RTP) layer, a realtime transport control protocol (RTCP) layer, or a secure RTP (SRTP) layer. Data input to the layer that performs the AL-FEC may be data subject to interleaving and encoding in the RTP or SRTP layer, and the layer that processes the AL-FEC may group data to symbols having the same priority, regardless of the type, priority, etc. of the data, and encode the symbols.

That is, as shown in FIG. 10, the AL-FEC divides an input source file or a source stream (S1010) into source blocks (S1020), configures source symbols for each source block (S1030), performs encoding on the source symbols to generate parity symbols (S1040), and encoding packets corresponding to the source symbols and packets corresponding to the parity symbols to generate encoded blocks (S1050).

As described above, transmission equipment that performs GD-FEC may have a protocol layer structure in the order of a GD-FEC processing layer, RTP & RTCP layers, SRTP & FEC layers, and a user datagram protocol (UDP).

Meanwhile, decoding delay of data subject to GD-FEC encoding may cause various problems such as switching time delay, etc. in the system.

Hereinafter, a method for minimizing delay in the GD-FEC method will be described.

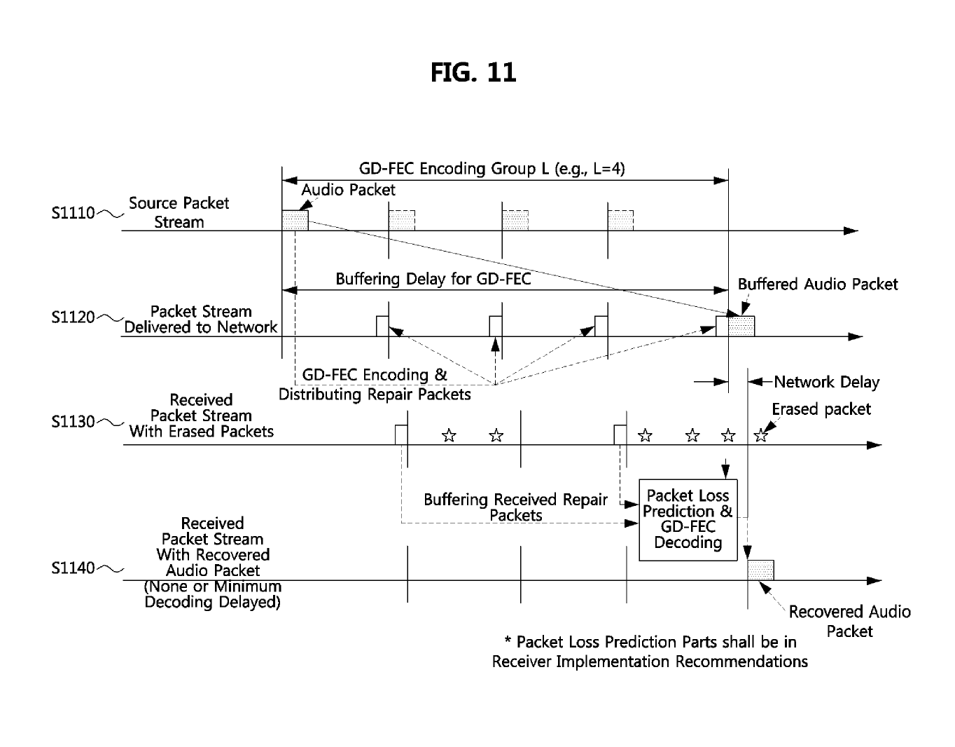

FIG. 11 is a view for explaining a process for minimizing decoding delay in the GD-FEC method, and shows an example of a GD-FEC method that is applied to a file delivery over unidirectional transport (FLUTE) protocol for streaming service.

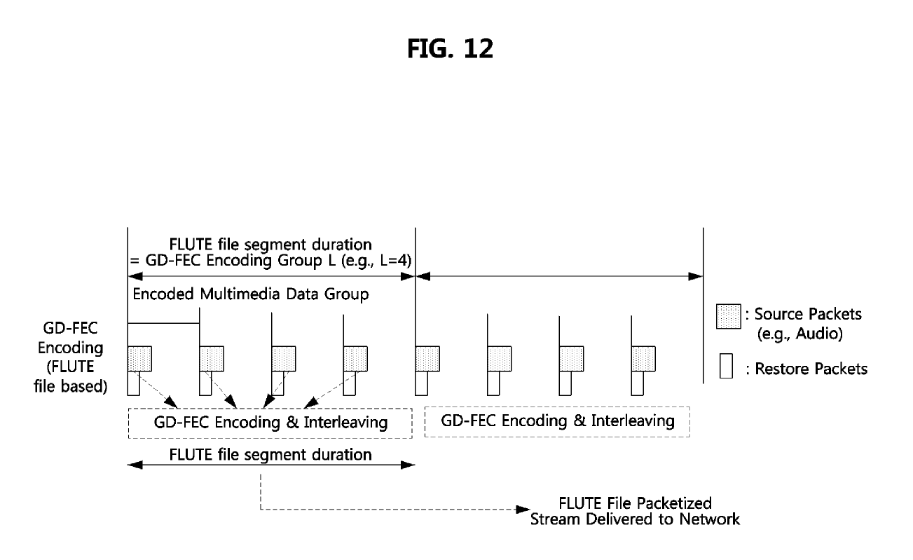

In detail, referring to FIG. 12, if a source packet stream is received, transmission equipment sets an encoding group including a predetermined number of time durations according to a predetermined parameter (for example, L=4) as described above (S1110), performs GD-FEC on packets (for example, audio packets) included in the individual time durations of the encoding group to generate repair packets for recovering lost packets when packet loss has occurred, and then distributes the repair packets to the individual time durations according to a predetermined rule.

Here, the repair packets are parity frames. As described above with reference to FIGS. 1 through 6, reference data groups to be subject to GD-FEC encoding in the individual time durations are decided according to predetermined priorities, and RaptorQ-link encoding is performed on the decided reference data groups to thereby generate the repair packets.

Also, the received source packet stream may be buffered in the transmission equipment, and then GD-FEC encoding may be performed on the buffered source packets. In this case, transmission delay (or buffering delay) may be generated by a time duration for which the GD-FEC is performed.

After the GD-FEC encoding is performed, the transmission equipment transmits the repair packets acquired through the GD-FEC encoding through a network (S1120).

Recovery equipment receives the repair packets transmitted from the transmission equipment (S1130). The recovery equipment may receive the repair packets after a predetermined time duration (that is, a transmission delay time through the network) has elapsed. Also, the recovery equipment may receive a part of the repair packets due to loss of some repair packets.

Then, the recovery equipment buffers the received repair packets, and recovers the audio packets using the buffered repair packets (S1140).

That is, according to the current embodiment, since transmission equipment acquires repair packets by performing GD-FEC encoding for the time duration of buffering for transmitting a packet stream, and transmits the repair packets to recovery equipment for the buffering time duration through a network so that the recovery equipment preferentially recovers packets using the repair packets, no delay due to GD-FEC encoding occurs although network transmission delay occurs, when source packets are transmitted by performing GD-FEC encoding.

FIG. 12 is a view for explaining a process for minimizing decoding delay in a GD-FEC method according to another embodiment of the present invention, and shows another example of a GD-FEC method that is applied to the FLUTE protocol for streaming service.

Referring to FIG. 12, in the current embodiment, the duration of a GD-FEC encoding group is set to be the same as a FLUTE file segment duration.

Accordingly, GD-FEC encoding may be performed for a time duration in which a FLUTE file segment is processed, so that no additional delay due to GD-FEC encoding occurs.

Also, according to another embodiment of the present invention, GD-FEC decoding may be performed for a time duration in which a FLUTE file segment is processed, so that no additional delay due to GD-FEC decoding occurs.

Specifically, the performance of GD-FEC may be improved through interleaving, and by setting a time duration for interleaving in unit of a FLUTE segment packet, additional delay due to interleaving may be prevented.

In addition, by dividing a FLUTE segment file to segment packets, and transmitting the segment packets according to predetermined priorities, instead of interleaving, the same effect as interleaving may be observed.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

1. A graceful degradation-forward error correction (GD-FEC) method comprising:
deciding a data group for encoding in a plurality of data streams being successively received over time, the data group for encoding configured with a predetermined number of time durations;
deciding at least one reference data group to be used for generating a parity frame in the individual time durations of the data group for encoding;
generating a parity frame using the at least one reference data group; and
distributing the parity frame into at least one time duration of a plurality of time durations including the time durations configuring the data group for encoding, according to a predetermined rule.

2. The GD-FEC method of claim 1, wherein the deciding of the reference data group comprises:
comparing the time lengths of frames corresponding to a reference data type having a highest priority among data types included in the individual data durations of the data group for encoding, to each other;
deciding the size of a frame having a longest time length among the frames, as a size of the reference data group; and
deciding the reference data group including at least one data type according to predetermined recovery priority in each time duration, based on the size of the reference data group.

3. The GD-FEC method of claim 1, wherein the generating of the parity frame comprises:
concatenating the reference data group to configure source data; and
performing encoding on the source data to generate the parity frame.

4. The GD-FEC method of claim 3, wherein the performing of the encoding on the source data to generate the parity frame comprises performing RaptorQ-like encoding on the source data to generate the parity frame.

5. The GD-FEC method of claim 1, wherein the generating of the parity frame comprises generating the parity frame according to a predetermined period configured in unit of the reference data group.

6. The GD-FEC method of claim 1, wherein the distributing of the parity frame comprises distributing the parity frame to a time duration before the time durations configuring the data group for encoding, or to at least one time duration among the time durations configuring the data group for encoding, according to a predetermined rule.

7. The GD-FEC method of claim 1, wherein the distributing of the parity frame comprises dividing the parity frame to generate two or more divided parity frames each having a predetermined length; and
distributing the two or more divided parity frames to time durations before the time durations configuring the data group for encoding, or to two or more time durations among the time durations configuring the data group for encoding.

8. The GD-FEC method of claim 7, wherein the generating of the divided parity frames comprises deciding the size of each divided parity frame, based on the number of reference data groups having to be recovered among a plurality of reference data groups each corresponding to the reference data group and the size of each reference data group.

9. The GD-FEC method of claim 1, wherein the deciding of the data group for encoding comprises:
deciding a Group of Picture (GoP) for each time duration having a predetermined length in pictures successively received over time; and
deciding the data group for encoding configured with a predetermined number of GoPs each corresponding to the GoP.

10. The GD-FEC method of claim 9, wherein the deciding of the reference data group comprises:
comparing the lengths of I pictures among picture types included in the individual GoPs configuring the data group for encoding, to each other;
deciding the length of an I picture having a longest length among the I pictures included in the individual GoPs, as a (the) size of the reference data group; and
deciding the reference data group including at least one picture type according to predetermined recovery priority in each GoP, based on the size of the reference data group.

11. A graceful degradation-forward error correction (GD-FEC) method which is performed by a transmission apparatus for transmitting multimedia data, comprising:
deciding a data group for encoding configured with a predetermined number of time durations in a received data stream;
deciding at least one reference data group to be used for generating a parity frame in the individual time durations included in the data group for encoding;
generating a parity frame using the at least one reference data group; and
transmitting the parity frame before transmitting data included in the data group for encoding.

12. The GD-FEC method of claim 11, wherein the generating of the parity frame comprises:
concatenating the reference data group to configure source data; and
performing RaptorQ-like encoding on the source data to generate the parity frame.

13. The GD-FEC method of claim 11, wherein the transmitting of the parity frame before transmitting the data included in the data group for encoding comprises transmitting the parity frame for a time duration in which the received data stream is buffered.

14. The GD-FEC method of claim 11, wherein the deciding of the data group for encoding configured with the predetermined number of time durations in the received data stream comprises deciding the time durations of the data group for encoding as the same duration per which a specific protocol segments and processes a file.

15. The GD-FEC method of claim 11, wherein the deciding of the data group for encoding configured with the predetermined number of time durations in the received data stream comprises deciding the time durations of the data group for encoding as the same duration as a file segment duration of a file delivery over unidirectional transport (FLUTE) protocol.

16. The GD-FEC method of claim 15, further comprising performing interleaving in unit of a segment packet resulting from dividing a segment file included in the file segment duration of the FLUTE protocol.

17. A graceful degradation-forward error correction (GD-FEC) apparatus comprising:
a first encoding layer configured to perform GD-FEC on received multimedia data;
a transport protocol processing layer configured to perform transport protocol processing on the data subject to the GD-FEC; and
a second encoding layer configured to perform application layer-forward error correction (AL-FEC) on the data subject to the transport protocol processing.

18. The GD-FEC apparatus of claim 17, wherein the first encoding layer performs the GD-FEC according to the type of the received multimedia data.
